(19) United States
(12) Patent Application Publication
(10) Pub. No.: US 2026/0068565 A1
(43) Pub. Date: Mar. 5, 2026

(54) SELECTIVE MATERIAL REMOVAL WITH ANGULAR BEAM

(71) Applicant: Applied Materials, Inc., Santa Clara, CA (US)

(72) Inventors: Mohammad Mahdi Tavakoli, Sunnyvale, CA (US); Joel Rigor, Santa Clara, CA (US); Avgerinos V. Gelatos, Scotts Valley, CA (US); Joung Joo Lee, San Jose, CA (US); Lei Jiang, San Ramon, CA (US); Ludovic Godet, Sunnyvale, CA (US)

(73) Assignee: Applied Materials, Inc., Santa Clara, CA (US)

(21) Appl. No.: 18/820,838

(22) Filed: Aug. 30, 2024

(51) Int. Cl. H01L 21/3213; H01L 21/768

(52) U.S. Cl. CPC H01L 21/32136

(57) ABSTRACT

Methods of filling a gap in a semiconductor substrate are described. A first material is formed on the substrate and in a gap formed in the substrate surface. The substrate is exposed to an angular etching process to remove the first material from the field of the substrate and a top portion of the sidewalls of the gap, leaving the first material in the bottom of the gap.

### TECHNICAL FIELD

Embodiments of the disclosure generally relate to apparatus and methods for selective etching of materials. In particular, embodiments of the disclosure relate to apparatus and methods for selectively etching materials using an angularly oriented beam of ions and/or radicals.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

Selective deposition, or selective film formation, is often a useful process in the formation of electronic devices. Selective deposition refers to a process in which a film is formed selectively, or preferentially, on one surface material relative to another surface material. Similarly, selective etching refers to a process where a film is etched from one surface material preferentially relative to a different surface material. For example, in a gapfill process, it is often helpful to have bottom-up growth of the gapfill material by selectively deposition the material on the bottom surface of the gap relative to the sidewalls or field of the substrate surface.

Conventional selective deposition processes can be time consuming and expensive. For example, in some current processes, a substrate is soaked with a precursor, followed by a selective etching process. This is expensive, requiring the use of two process chambers, and is time consuming.

There is an ongoing need in the art for apparatus and methods to selectively form materials on substrate surfaces or within surface structures.

### SUMMARY

In some aspects, the techniques described herein relate to a method of filling a gap in a semiconductor substrate, the method including: forming a first material on the semiconductor substrate having the gap, the gap having sidewalls and a bottom, the first material formed on the field of the semiconductor substrate outside of the gap, on the sidewalls and bottom of the gap; and exposing the semiconductor substrate to an angular etching process to remove a first material from a field of the semiconductor substrate and a top portion of the sidewalls of the gap, leaving the first material on the bottom of the gap.

In some aspects, the techniques described herein relate to a method of filling a gap in a semiconductor substrate, the method including: forming a first material on a substrate surface having a gap formed therein, the gap having a bottom and at least one sidewall and a depth measured from a field of the substrate surface to the bottom of the gap, the bottom of the gap including a conductive material, the at least one sidewall of the gap including a dielectric material, the first material forming on the field of the substrate surface, the at least one sidewall and the bottom of the gap, the first material having a greater thickness on the field of the substrate surface and the bottom of the gap than the at least one sidewall of the gap; exposing the first material to an angular etch to reduce a thickness of the first material on the field of the substrate surface; plasma etching the first material from the substrate surface and the at least one sidewall leaving a first material seed layer on the bottom of the gap; and filling the structure in a bottom-up manner with first material to fill the gap.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a semiconductor manufacturing processing chamber with a recirculation pump in the expanded position in accordance with one or more embodiments of the disclosure.

FIG. 2 shows an expanded view of a semiconductor substrate with a gap in accordance with one or more embodiments of the disclosure.

FIGS. 3A through 3D illustrate a method of filling a gap in a semiconductor substrate in accordance with one or more embodiments of the disclosure.

FIGS. 4A through 4D illustrate another embodiment of the method in which the angular etch is used to prepare a seed layer at the bottom of the gap.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of the a spatial ALD process chamber, a gas curtain is formed by a combination of purge gas ports and vacuum ports to maintain separation between the reactive gases to prevent gas-phase reactions.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

One or more embodiments of the disclosure advantageously provide approaches to selectively etch materials from a top of a surface structure without affecting the bottom of the structure. Some embodiments advantageously provide a seed layer at the bottom of a trench or via. Some embodiments allow for the removal of material from the field of the substrate surface without damaging the sidewall and/or bottom of the structure. Some embodiments allow for the removal of overhanging material caused by PVD deposition which can result in the pinching-off of gaps resulting in seams or voids in the gapfill material. Some embodiments advantageously are performed in a single processing chamber.

In one or more embodiments of the disclosure, a process for forming a film allows for the selective etching of materials (e.g., tungsten) from the top of a trench or via structure but not the bottom. In some embodiments, pure oxygen (O₂) or a combination of oxygen (O₂) and carbon tetrafluoride (CF₄), with an angular beam selectively etches tungsten from the top of the structure only.

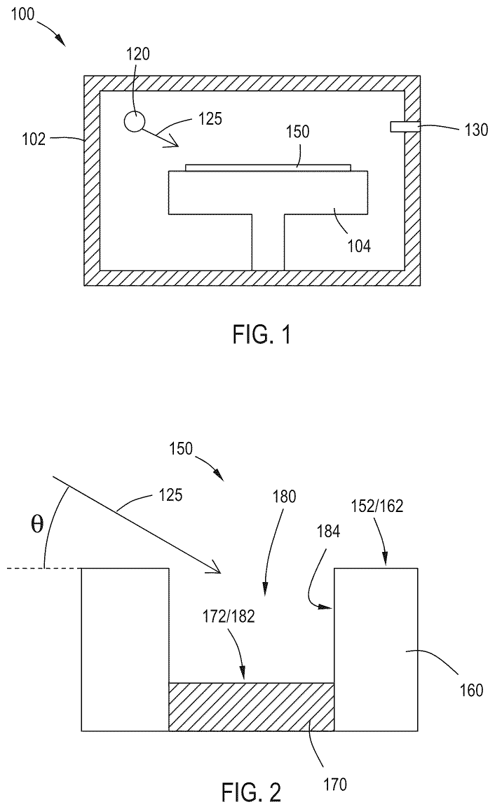

FIG. 1 shows a schematic representation of a semiconductor manufacturing processing chamber 100 with an angular beam source 120 in accordance with one or more embodiments of the disclosure. The semiconductor manufacturing processing chamber 100 comprises a chamber body 102 and a substrate support 104. The substrate support 104 is configured to support a semiconductor substrate 150 during processing. The substrate support 104 of some embodiments can move the semiconductor substrate 150 vertically and/or rotationally around an axis of the substrate support 104.

The semiconductor manufacturing processing chamber 100 includes an angular beam source 120 configured to perform an angular etching process 125. The angular beam source 120 of some embodiment is configured to move within the interior of the semiconductor manufacturing processing chamber 100 in a path parallel to the surface of the substrate support 110. Stated differently, the angular beam source 120 of some embodiments is configured to translate across the interior of the semiconductor manufacturing processing chamber 100 to ensure that the angular etching process 125 passes across the entire substrate surface. The skilled artisan will be familiar with the mechanical components used to move or rotate the substrate support 104 and/or angular beam source 120. Suitable components include but are not limited to, motors and actuators.

In some embodiments, the angular beam source 120, also referred to as a ribbon source, has a width greater than or equal to a width of the semiconductor substrate 150. Having a ribbon source that is wider than the semiconductor substrate 150 helps to ensure that the angular etching process 125 covers the entire surface of the semiconductor substrate 150.

In some embodiments, the substrate support 110 comprises one or more of an electrostatic chuck or a heater. The skilled artisan will understand the construction and operation of both electrostatic chucks and heaters. In some embodiments, the temperature of the semiconductor substrate 150 is controlled on the substrate support 110 using the heater. In some embodiments, the semiconductor substrate 150 is maintained at a temperature in the range of room temperature (25° C.) to 250° C., or in the range of 50° C. to 225° C., or in the range of 75° C. to 200° C., or in the range of 100° C. to 175° C.

The semiconductor manufacturing processing chamber 100 has an inlet/outlet 130 in a wall of the chamber body 102. The outlet 130 can be used to flow a gas into the interior of the semiconductor manufacturing processing chamber 100 or to evacuate gases from the interior of the semiconductor manufacturing processing chamber 100. The skilled artisan will be familiar with the operation of a semiconductor manufacturing processing chamber 100 including the components used to provide gas flows into and/or out of the chamber interior. In some embodiments, there is a gas inlet in fluid communication with the angular beam source 120 so that the angular beam generates ions and/or radicals from the gas flowing through the angular beam source 120 into the chamber interior.

FIG. 2 shows an expanded view of a semiconductor substrate 150 with a gap 180 in accordance with one or more embodiments of the disclosure. The semiconductor substrate 150 has a substrate surface 152 and the gap 180 is formed in the substrate surface 152 and extends a depth into the semiconductor substrate 150. In the illustrated embodiment, the semiconductor substrate 150 comprises a dielectric material 160 and a conductive material 170. The gap 180 extends into the semiconductor substrate 150 from the substrate surface 152 to form the gap 180 through the dielectric material 160 and exposing the top surface 172 of the conductive material 170. The substrate surface 152 is formed as the top surface or field 162 of the dielectric material 160. The at least one sidewall 184 of the gap 180 are formed in the dielectric material 160. The top surface 172 of the conductive material 170 is the bottom 182 of the gap 180.

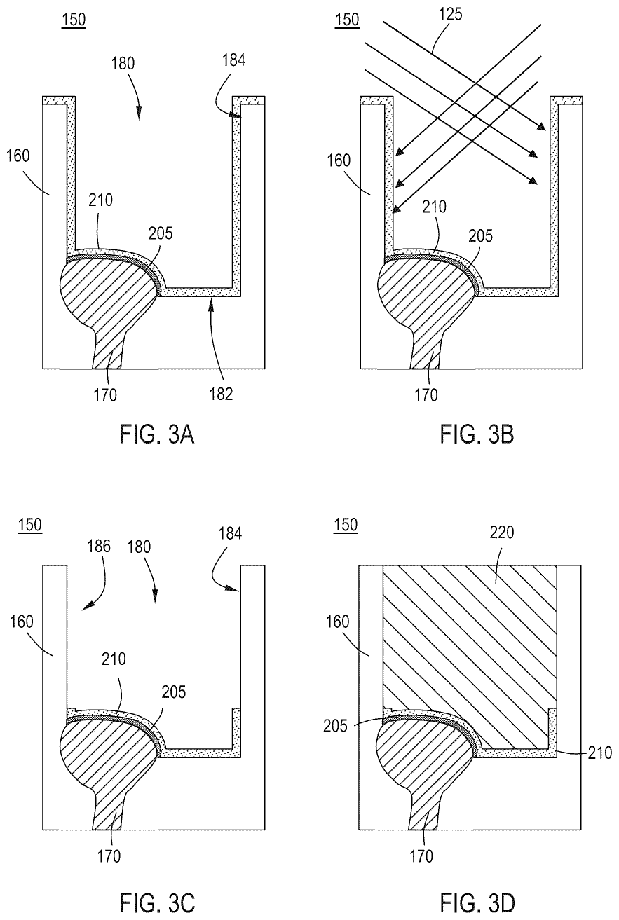

FIGS. 3A through 3D illustrate a method of filling a gap 180 in a semiconductor substrate 150 in accordance with one or more embodiments of the disclosure. FIG. 3A illustrates a semiconductor substrate 150 with a gap 180 formed in the substrate surface 152. The gap 180 can be any suitable opening in the substrate surface 152; for example, a trench or a via. The gap 180 has a bottom 182 and sidewalls 184. While the illustrated embodiment shows a single gap 180, the skilled artisan will recognize that there can be any number of gaps, trenches or vias. The sidewalls 184 of the gap 180 are formed by the dielectric material 160, while the bottom 182 of the gap 180 comprises a conductive material 170.

A first material 210 is formed on the semiconductor substrate 150. The first material 210 of some embodiments is formed on the field 162 of the substrate surface 152 outside of the gap 180, on the sidewalls 184 and the bottom 182 of the gap 180. The gap 180 may be described as having sidewalls 184; however, the skilled artisan will recognize that a via is typically a cylindrical component which may be considered to have a single circular sidewall. Vias with a single circular sidewall, when shown in cross-section like the Figures, has two sides. The skilled artisan will understand that the term “sidewalls” refers to the walls of both trench and via surface structures.

The first material 210 can be any suitable material known to the skilled artisan. In some embodiments, the first material 210 comprises one or more of titanium silicide, tungsten, titanium, molybdenum, titanium nitride, tungsten carbide, ruthenium, ruthenium oxide, zirconium or tantalum nitride.

In FIG. 3B, the semiconductor substrate 150 is exposed to an angular etching process 125. The angular etching process 125 of some embodiments comprises a angular beam source 120, also referred to as a ribbon source, that directs a stream of radicals and/or ions toward the substrate surface 152. The ribbon source creates a directional flow of ions and/or radicals at an angle to the substrate surface 152. As used herein, an angle of 0° is considered to be normal to (perpendicular to) the plane of the substrate surface 152. In some embodiments, the angular beam source 120 is configured so that the angular etching process 125 directs ions and/or radicals at the substrate surface 152 at an angle in the range of 50° to 85°, or in the range of 50° to 80°, or in the range of 55° to 75°, or in the range of 60° to 70°, where 0° is normal to the field of the semiconductor substrate. In some embodiments, the angle is sufficient to prevent ions or radicals from being directed to the bottom of the gap 180.

The angular etching process 125 of some embodiment comprises comprises oxidizing or nitridating the first material 210 and directing ions toward the semiconductor substrate 150 at an angle from a ribbon source. In some embodiments, the angular etch comprises radicals generated from one or more of Ar, CHF₃, SF₆, NF₃, CH₃F, CH₄, O₂, Cl₂ or CF₄. In some embodiments, the angular etch further comprises adding one or more of CF₄ or Cl₂ to accelerate the etch rate. In some embodiments, nitrogen or oxygen do not damage the dielectric. In some embodiments, fluorine and chlorine may cause damage to the dielectric but have an accelerated material etch rate relative to the nitrogen and oxygen etch. In some embodiments, the angular etch comprises ions generated from one or more of N₂, O₂, Cl₂ or CF₄.

As shown in FIG. 3C, the angular etching process 125 removes the first material 210 from a field 162 of the semiconductor substrate 150 and a top portion 186 of the sidewalls 184 of the gap 180. In some embodiments, the angular etching process 125 leaves the first material 210 on the bottom 182 of the gap 180.

After the first material 210 has been removed from the top portion 186 of the at least one sidewall 184 of the gap 180, as shown in FIG. 3D, the gap 180 is filled with a gapfill material 220. The gapfill material 220 can be deposited by any suitable technique known to the skilled artisan including, but not limited to, chemical vapor deposition (CVD), plasma-enhanced chemical vapor deposition (PECVD), atomic layer deposition (ALD) and plasma-enhanced atomic layer deposition (PEALD).

The gapfill material 220 can be any suitable material. In some embodiments, the gapfill material 220 comprises the same material as the first material 210. In some embodiments, the gapfill material 220 is a different material than the first material 210.

In some embodiments, as shown in the Figures, a liner 205 material is deposited on the conductive material 170 prior to the deposition of the first material 210. The liner 205 can be any suitable material known to the skilled artisan depending on, for example, the composition of the conductive material 170, the first material 210 and the gapfill material 220. In some embodiments, the first material 210 acts as the seed layer for the gapfill material 220 when both the first material 210 and gapfill material 220 comprise the same material.

In some embodiments, the dielectric material 160 comprises silicon nitride and the conductive material 170 comprises silicon. In one or more embodiments, the liner 205 comprises titanium silicon nitride. In some embodiments, the first material 210 comprises titanium silicide. In some embodiments, the gapfill material 220 comprises tungsten (W), deposited by chemical vapor deposition.

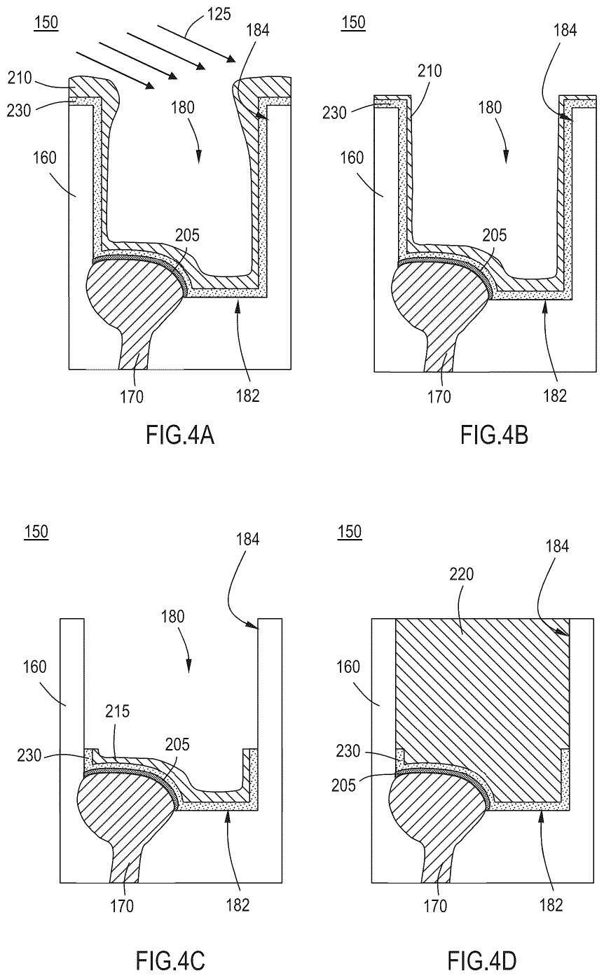

FIGS. 4A through 4D illustrate another embodiment of the method which the angular etch is used to prepare a seed layer at the bottom of the gap 180. As shown in FIG. 4A, a first material 210 is formed on the substrate surface 152 using a suitable deposition technique. In some embodiments, the first material 210 is deposited by physical vapor deposition (PVD), resulting in a first material 210 with a greater thickness on the field 162 of the substrate surface 152 and the bottom 182 of the gap 180 relative to the at least one sidewall 184 of the gap 180. The deposition process for forming the first material 210 is a directional process using a biased substrate resulting in the overhang material forming at the top portion of the gap 180. In the illustrated embodiment, the conductive material 170 at the bottom 182 of the gap 180 has a liner 205. A second material 230 is formed on the field 162, the sidewalls 184 and the bottom 182 of the gap 180. In some embodiments, the second material 230 is a material deposited conformally by an suitable technique including, but not limited to, atomic layer deposition.

After exposing the first material 210 to the angular etching process 125 in FIG. 4A, the thickness of the first material 210 is reduced on the field 162 of the substrate surface 152, as shown in FIG. 4B. The angular etching process 125 of some embodiments results in first material 210 with a gradient thickness, with the thickest portion at the bottom 182 of the gap 180.

FIG. 4C shows the embodiment of FIG. 4B after exposing the semiconductor substrate 150 to a plasma etching process to remove the first material 210 from the substrate surface 152 and the top portion 186 of the sidewalls 184 of the gap 180. This leaves a first material seed layer 215 at the bottom of the gap 180. In some embodiments, as shown in the Figures, the plasma etching process also removes the second material 230 with the first material 210 leaving the surfaces of the dielectric material 160 exposed.

In some embodiments, the plasma etching process to remove the first material comprises an inductively coupled plasma (ICP) oxidation and exposure to tungsten pentachloride (WCl₅). ICP plasma and WCl₅ gas can damage the underneath layer (TiSi) and Epi.

FIG. 4D shows the embodiment of FIG. 4C after filling the gap 180 in a bottom-up manner with additional first material 210 to create a gapfill material 220. In some embodiments, the gapfill material 220 is formed by chemical vapor deposition.

In a prophetic example, a structure having tungsten (W) or titanium (Ti) material would be prepared and loaded into a suitable processing chamber. An ion beam using O and CF₄ radicals can be used to create fluorine ions with angular direction of about 60° and will etch away only the W from the top of the structure not from the bottom. During the process, the wafer can be rotated and the pedestal temperature held at room temperature. Twenty scans of the beam across the substate surface can consume all fluorine chemistries on the field (in a starving mode) so the fluorine ions do not reach the bottom of the structure. An amount of argon (Ar) and nitrogen (N₂) can be added to increase beam stability. Pressure can be maintained at about 3E-5Torr, power for the O₂ source is about 1500 W and power for Ar is about 750 W. The ratio of the flows of Ar, N₂, O₂ and CF₄ is about 2:2:10:50 sccm.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of filling a gap in a semiconductor substrate, the method comprising:
forming a first material on the semiconductor substrate having the gap, the gap having sidewalls and a bottom, the first material formed on a field of the semiconductor substrate outside of the gap, on the sidewalls and bottom of the gap; and
exposing the semiconductor substrate to an angular etching process to remove a first material from a field of the semiconductor substrate and a top portion of the sidewalls of the gap, leaving the first material on the bottom of the gap.

2. The method of claim 1, wherein the first material comprises one or more of titanium silicide, tungsten, titanium, molybdenum, titanium nitride, tungsten carbide, ruthenium, ruthenium oxide, zirconium or tantalum nitride.

3. The method of claim 1, wherein the angular etch comprises oxidizing or nitridating the first material and directing ions toward the semiconductor substrate at an angle from a ribbon source.

4. The method of claim 3, wherein the angle is in the range of 50° to 85°, where 0° is normal to the field of the semiconductor substrate.

5. The method of claim 3, wherein the angle is sufficient to prevent ions or radicals from being directed to the bottom of the gap.

6. The method of claim 3, wherein the ribbon source has a width greater than or equal to a width of the semiconductor substrate.

7. The method of claim 3, wherein the angular etch further comprises adding one or more of CF₄ or Cl₂ to accelerate etch rate.

8. The method of claim 3, wherein the angular etch comprises ions generated from one or more of N₂, O₂, Cl₂ or CF₄.

9. The method of claim 1, wherein the semiconductor substrate is maintained at temperature in the range of room temperature to 250° C.

10. The method of claim 1, wherein the sidewalls comprise silicon nitride and the bottom comprises titanium silicon nitride.

11. A method of filling a gap in a semiconductor substrate, the method comprising:
forming a first material on a substrate surface having a gap formed therein, the gap having a bottom and at least one sidewall and a depth measured from a field of the substrate surface to the bottom of the gap, the bottom of the gap comprising a conductive material, the at least one sidewall of the gap comprising a dielectric material, the first material forming on the field of the substrate surface, the at least one sidewall and the bottom of the gap, the first material having a greater thickness on the field of the substrate surface and the bottom of the gap than the at least one sidewall of the gap;
exposing the first material to an angular etch to reduce a thickness of the first material on the field of the substrate surface;
plasma etching the first material from the substrate surface and the at least one sidewall leaving a first material seed layer on the bottom of the gap; and
filling the gap in a bottom-up manner with first material to fill the gap.

12. The method of claim 11, wherein the first material comprises one or more of titanium silicide, tungsten, titanium, molybdenum, titanium nitride, tungsten carbide, ruthenium, ruthenium oxide, zirconium or tantalum nitride

13. The method of claim 11, wherein the first material is deposited by physical vapor deposition (PVD).

14. The method of claim 13, wherein the angular etch comprises a ribbon source directing one or more of ions or radicals toward the semiconductor substrate at an angle sufficient to prevent ions or radicals from etching first material from the bottom of the gap.

15. The method of claim 14, wherein the ribbon source has a width greater than or equal to a width of the semiconductor substrate.

16. The method of claim 13, wherein the semiconductor substrate is rotated during the angular etch.

17. The method of claim 13, wherein the angular etch comprises ions generated from one or more of N₂, O₂, Cl₂ or CF₄.

18. The method of claim 13, wherein the plasma etching the first material comprises an inductively couple plasma (ICP) oxidation and exposure to tungsten pentachloride (WCl₅).

19. The method of claim 18, wherein filling the gap comprises deposition of the first material by chemical vapor deposition (CVD).
